(19) United States
(12) Patent Application Publication
(10) Pub. No.: US 2025/0098297 A1
(43) Pub. Date: Mar. 20, 2025

(54) COMPOSITE SEMICONDUCTOR SUBSTRATE

(71) Applicant: Invention and Collaboration Laboratory, Inc., Taipei City (TW)

(72) Inventor: Chao-Chun Lu, Taipei City (TW)

(73) Assignee: Invention and Collaboration Laboratory, Inc., Taipei City (TW)

(21) Appl. No.: 18/884,139

(22) Filed: Sep. 13, 2024

Related U.S. Application Data
(60) Provisional application No. 63/538,533, filed on Sep. 15, 2023.

(51) Int. Cl. H01L 27/092; H01L 27/02

(52) U.S. Cl. CPC H10D 84/859; H10D 89/00

(57) ABSTRACT

A composite semiconductor substrate includes a bulk semiconductor substrate and a first well region. The bulk semiconductor substrate has an original semiconductor surface and with a first doping type. The first well region is in the bulk semiconductor substrate with a second doping type, wherein the first doping type is different from the second doping type. There is no PN junction between the bulk semiconductor substrate and the first well region.

### CROSS REFERENCE TO RELATED APPLICATIONS

This application claims the benefit of U.S. Provisional Application No. 63/538,533, filed on Sep. 15, 2023. The content of the application is incorporated herein by reference.

### BACKGROUND OF THE INVENTION

### 1. Field of the Invention

The present invention relates to a composite semiconductor substrate with Deep-well-Trench-Isolation (DWTI) and Horizontal-well-Isolation (HWI), and particularly to a composite semiconductor substrate that can fully isolate Box-wells from one another, eliminate the complex p/n-junction isolations in the conventional CMOS process, significantly reduce the Latch-up problems which CMOS devices mostly suffer from, minimize the leakage mechanism due to p/n junction isolation among wells and devices due to incomplete isolations of various wells, be much better scalable in both vertical and horizontal dimensions as the CMOS circuits/devices must be further scaled, reduce power dissipation due to junction isolations, reduce noise disturbance (especially due to long-distance drifted minority carriers), use the suitable Z-material to improve the thermal dissipation and the thermal temperature due to hot operations, no complicated triple well formation process and decrease well separation due to triple well process, and the mechanical strengths due to Box-well with both HWI and DWTI should be helpful If the wafer must be made thinner.

### 2. Description of the Prior Art

At present CMOS (Complementary Metal-Oxide-Semiconductor) technologies have been most widely used to support GSIC (Giga-Scale Integrated Circuits; a silicon die containing a number of billions of transistors which have minimum feature-size dimensions as small as several nanometers). The most generally used CMOS structure has its wafer substrate starting from p-type doped silicon wafer 102 (FIG. 1A). The CMOS design needs to use NMOS (n-type Metal-Oxide-Semiconductor) transistors with their device substrates in a p-type material (or p-well 104) and to use PMOS (p-type Metal-Oxide-Semiconductor) transistors with their device substrates in an n-type material (or n-well 106). These many n-wells in a die are formed by either ion-implantation or diffusion of n-type dopants into the p-type wafer substrate (or p-well) so as to host many PMOS transistors inside these n-wells. The p-type doped silicon wafer 102 extending the entire wafer is named as bulk wafer substrate (BWS) which is usually biased at an electrical potential of zero volt as a ground electrode through a design of supplying 0 V either from multiple top n+ contacts or from the back of BWS, and hosts many NMOS transistors. The wells formed into these p-type BWS are named here as single n-well (for hosting PMOS transistors) which is usually biased at an electrical potential of some positive voltage (such as 3.3V, 1.8V, 1.2V, 0.9V or 0.75V) as a VDD electrode. As VDD and ground voltages are applied to n-well and p-type BWS, respectively, such a resulted reverse-biased condition across the p-n junction can effectively form a natural electrical isolation for stabilizing transistor operations using its own substrate. This kind of n-well structure for CMOS devices is named as single-well (SW) in the p-type wafer substrate. In addition, as shown in FIG. 1A, STI is an abbreviation of shallow trench isolation.

For more complex CMOS device constructions there can have various well structures designed. One structure, for example, is named as Double- or Twin-well (DW). That is, in order to form some desired special electrical property a higher concentration p-doped well is created inside the bulk p-type wafer, and both of which can share an equal electrical potential like 0V as a ground without conflicting.

Please refer to FIG. 1B. FIG. 1B is a diagram illustrating another example of CMOS well structure. As shown in FIG. 1B, the CMOS well structure can be designed to have a p-well 108 (named as Triple-well, TW) inside an n-well 110 in a p-type silicon wafer substrate 112 and, therefore, there are NMOS transistors with desired characteristics by applying a different electrical potential to this Triple-well (usually named as Vsub, for instance, at −0.5V or other negative values) electrical potential of which can be thus differentiated from the electrical potential of the p-type silicon wafer substrate 112 biased at 0V. One example of the necessity of creating a TW structure can be referred to the DRAM (dynamic random-access memory) cell array in CMOS DRAMs. The DRAM's 1T1C cell must have its NMOS access transistor (1T) to be positioned inside a cell-array's p-well (TW or named as CA-well) which must be isolated from other support circuits located in separate wells or BWS since such a p-type CA-well must be biased at a negative voltage of Vsub like −0.5V. This CA-well is usually created by some high-energy (e.g. Mega-eV) ion-implantation of p-type dopants into the n-type SW, and is thus usually called as a triple-well (TW) CMOS DRAM technology. The voltages biased at the cell array and n-well are set up like Vsub for CA of −0.5V and 1.2V, respectively, in order to form a pn-junction isolation between two wells. Besides this example illustrating DRAM cell-array needs, many logic chips for many applications which also must create TW CMOS for hosing CMOS devices in different well structures.

Although well structures in CMOS technologies are so important, the conventional ways of using either diffusion or ion-implantation techniques from the top surface into the silicon wafers have been used for several decades without inventing any other better techniques. As advanced CMOS technology requires to be further scaled down to result in much smaller geometries in three x-y-z dimensions, using the conventional p/n-junctions by silicon materials to form the electrical isolations (or separations) between various well structures has the following weaknesses: (1) the p/n-junction separation distance does consume quite a large area to divide the wells in both horizontal and vertical directions; (2) these p/n-junctions cause serious disadvantages such as easily triggering possible CMOS latch-up phenomenon to shut down CMOS circuits even up to chip mis-operations; (3) in current chip design the silicon bulk substrate is viewed as a reasonably good material for dissipating thermal power, which generated heat (abbreviated as TPH) from circuit operations, but up to today's Giga-scale Integration (GSI) and for future Tera-scale Integration (TSI) much better TPH methods must be invented and used; and (4) the electrical potential fluctuations among these p/n-junctions as widely connected bodies could make the substrate potentials of circuits to be fallen into unstable states which hardly minimize extra noise generations and propagations, etc.

Therefore, the present invention disclosed here are introducing new concepts of forming well structures for CMOS technologies and proposing several exemplified novel fabrications methods to achieve such new well-structure concepts.

### SUMMARY OF THE INVENTION

An embodiment of the present invention provides a composite semiconductor substrate. The composite semiconductor substrate includes a bulk semiconductor substrate and a first well region. The bulk semiconductor substrate has an original semiconductor surface and with a first doping type. The first well region is in the bulk semiconductor substrate with a second doping type, wherein the first doping type is different from the second doping type. There is no PN junction between the bulk semiconductor substrate and the first well region.

According to one aspect of the invention, the composite semiconductor substrate further includes a deep well trench isolation region and a horizontal well isolation region. The deep well trench isolation region surrounds sidewalls of the first well region. The horizontal well isolation region is under a bottom surface of the first well region. A combination of the deep well trench isolation region and the horizontal well isolation region fully isolates the first well region from other portion of the bulk semiconductor substrate.

According to one aspect of the invention, two sidewalls of the horizontal well isolation region abut against the deep well trench isolation region.

According to one aspect of the invention, a vertical depth of the deep well trench isolation region is 50˜400 nm or 400˜1200 nm.

According to one aspect of the invention, a vertical depth of the horizontal well isolation region is 50˜200 nm.

According to one aspect of the invention, either the deep well trench isolation region or the horizontal well isolation region includes a high-thermal-conductivity material which has a thermal conductivity higher than that of the SiO₂ or silicon.

According to one aspect of the invention, the first doping type is p doping type, and the second doping type is n doping type.

According to one aspect of the invention, the composite semiconductor substrate further includes a PMOS (p-type Metal-Oxide-Semiconductor) transistor and a shallow trench isolation region. The PMOS transistor is in the first well region. The shallow trench isolation region surrounds the PMOS transistor. A vertical depth of the deep well trench isolation region is larger than that of the shallow trench isolation region.

Another embodiment of the present invention provides a composite semiconductor substrate. The composite semiconductor substrate includes a bulk semiconductor substrate a first well region. The bulk semiconductor substrate has an original semiconductor surface and with a first doping type. The first well region is in the bulk semiconductor substrate with a second doping type. There is no electrical current path between a bottom of the first well region and other portion of the bulk semiconductor substrate, and there is no electrical current path between sidewalls of the first well region and the other portion of the bulk semiconductor substrate.

According to one aspect of the invention, the composite semiconductor substrate further includes a deep well trench isolation region and a horizontal well isolation region. The deep well trench isolation region surrounds sidewalls of the first well region. The horizontal well isolation region is under a bottom surface of the first well region. A combination of the deep well trench isolation region and the horizontal well isolation region fully isolates the first well region from other portion of the bulk semiconductor substrate.

According to one aspect of the invention, the horizontal well isolation region comprising a material made of oxide, nitride, or high thermal conductivity material.

According to one aspect of the invention, the horizontal well isolation region comprising two oxide layers and a high thermal conductivity layer between the two oxide layers.

According to one aspect of the invention, both the first doping type and the second doping type are p doping type.

According to one aspect of the invention, a doping concentration of the first doping type is different from that of the second doping type.

According to one aspect of the invention, the composite semiconductor substrate further includes an NMOS (n-type Metal-Oxide-Semiconductor) transistor and a shallow trench isolation region. The NMOS transistor is in the first well region. The shallow trench isolation region surrounds the NMOS transistor. A vertical depth of the deep well trench isolation region is larger than that of the shallow trench isolation region.

According to one aspect of the invention, either the deep well trench isolation region or the shallow trench isolation region includes a high-thermal-conductivity material which has a thermal conductivity higher than that of the SiO₂ or silicon.

Another embodiment of the present invention provides a composite semiconductor substrate. The composite semiconductor substrate includes a bulk semiconductor substrate, a first well region, and a second well region. The bulk semiconductor substrate has an original semiconductor surface and with a first doping type. The first well region is in the bulk semiconductor substrate with a second doping type. The second well region is in the bulk semiconductor substrate with the first doping type. There is no electrical current path between a bottom of the first well region and other portion of the bulk semiconductor substrate, and there is no electrical current path between a bottom of the second well region and the other portion of the bulk semiconductor substrate.

According to one aspect of the invention, the composite semiconductor substrate further includes a first deep well trench isolation region and a first horizontal well isolation region. The first deep well trench isolation region surrounds sidewalls of the first well region. The first horizontal well isolation region is under a bottom surface of the first well region. A combination of the first deep well trench isolation region and the first horizontal well isolation region fully isolates the first well region from other portion of the bulk semiconductor substrate.

According to one aspect of the invention, the composite semiconductor substrate further includes a second deep well trench isolation region and a second horizontal well isolation region. The second deep well trench isolation region surrounds sidewalls of the second well region. The second horizontal well isolation region is under a bottom surface of the second well region. A combination of the second deep well trench isolation region and the second horizontal well isolation region fully isolates the second well region from other portion of the bulk semiconductor substrate.

According to one aspect of the invention, a vertical depth of the first well region or the second well region is around 40˜100 nm.

According to one aspect of the invention, the composite semiconductor substrate further includes an NMOS transistor and a first shallow trench isolation region. The NMOS transistor is in the first well region. The first shallow trench isolation region surrounds the NMOS transistor. A vertical depth of the first deep well trench isolation region is larger than that of the first shallow trench isolation region.

According to one aspect of the invention, the composite semiconductor substrate further includes a PMOS transistor and a second shallow trench isolation region. The PMOS transistor is in the second well region. The second shallow trench isolation region surrounds the NMOS transistor. A vertical depth of the second deep well trench isolation region is larger than that of the second shallow trench isolation region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A is a diagram illustrating an example of CMOS well structure according to the prior art.

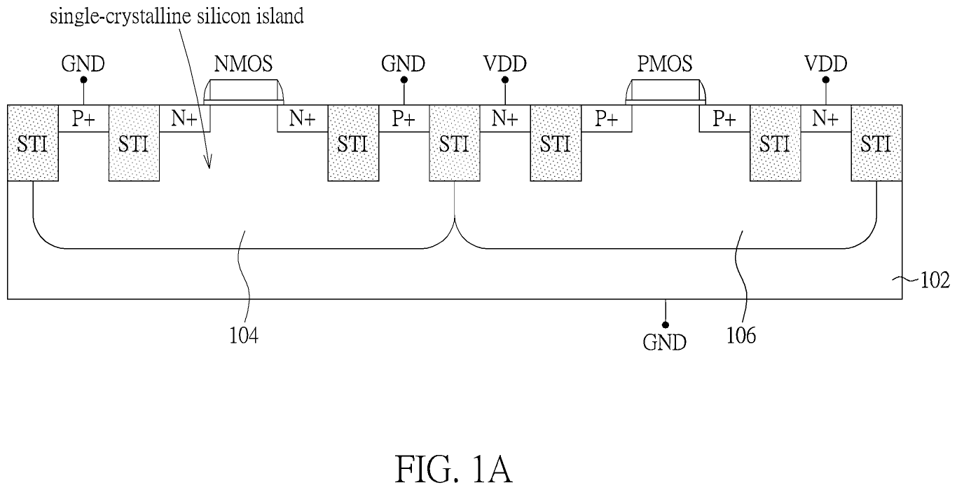

FIG. 1B is a diagram illustrating another example of CMOS well structure according to the prior art.

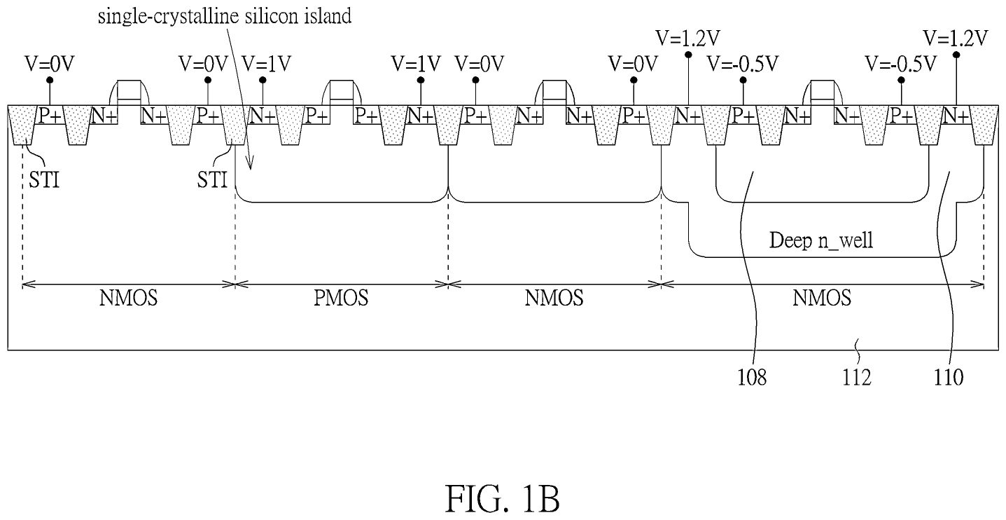

FIG. 2 is a diagram illustrating a new type of insulation (or isolation) structure to separate different wells in the vertical dimension according to an embodiment of the present invention.

FIG. 3 is a flowchart illustrating a manufacturing method of a composite semiconductor substrate with DWTI and HWI according to an embodiment of the present invention.

FIG. 4 is a diagram illustrating growing a pad-oxide layer and then depositing a pad-nitride layer.

FIG. 5 is a diagram illustrating defining a well region and removing the pad-nitride layer, the pad-oxide layer and parts of a silicon material outside the well region, and then forming a shallow trench isolation (STI).

FIG. 6 is a diagram illustrating etching down the STI, then growing a vertical pad-oxide layer, and then forming a vertical pad-nitride spacer.

FIG. 7 is a diagram illustrating etching down the STI continuously and then etching the exposed vertical silicon surfaces to create vertical silicon pillar.

FIG. 8 is a diagram illustrating etching the vertical silicon pillar to form hollow spaces and a middle silicon column, and then using the thermal oxidation to grow out of untouched silicon areas within the hollow spaces.

FIG. 9 is a diagram illustrating depositing a suitable Z-material to fill the open areas inside the hollow regions, and then deposit a thick oxide layer.

FIG. 10 is a diagram illustrating using the CMP technique on the thick oxide layer.

### DETAILED DESCRIPTION

The key concept breakthrough is to use insulating materials (insulators) instead of p/n-junctions to separate different wells from one another. These insulators can be using conventional oxide layers or even more suitable materials which have higher thermal conductivity and can perform better and faster power-dissipation results. Further exploration can even result in better insulator layers on the back side of the silicon wafers to dissipate thermal heat more effectively.

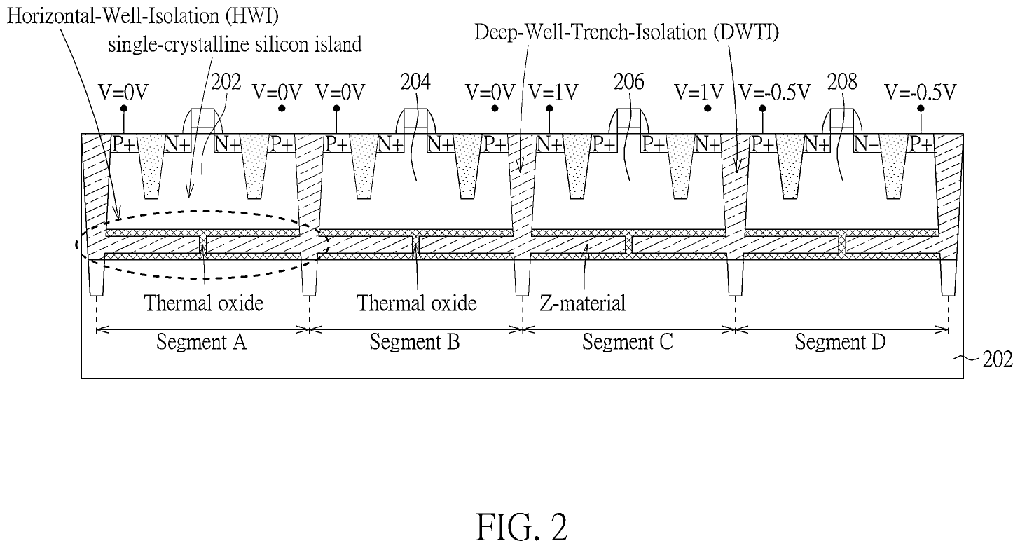

FIG. 2 shows an example of the new CMOS technology using such inventions to create new box-well structures hosting various NMOS and PMOS transistors, respectively. The segment A in FIG. 2 shows an NMOS transistor in the p-type bulk substrate wafer 202 (e.g. biased at 0V). The segment B shows an NMOS transistor in a p-type twin-well 204 (e.g. biased at 0V). The segment C shows a PMOS transistor in an n-type single-well 206 (e.g. biased at 1V). The segment D shows an NMOS transistor located inside a p-type triple-well 208 (e.g. biased at Vsub=−0.5V). It is noted here that by using insulators to isolate various well functions there is no so-called triple-well p/n-junctions but simple P-well which can be biased at any Vsub value.

As shown in FIG. 2, a new type of insulation (or isolation) structure to separate different wells in the vertical dimension is created along the vertical z-dimension and is named as Deep-well-Trench-Isolation (DWTI). Another type of insulation (or isolation) structure to separate well from the substrate horizontally along the x-y dimensions and is thus named as Horizontal-well-Isolation (HWI).

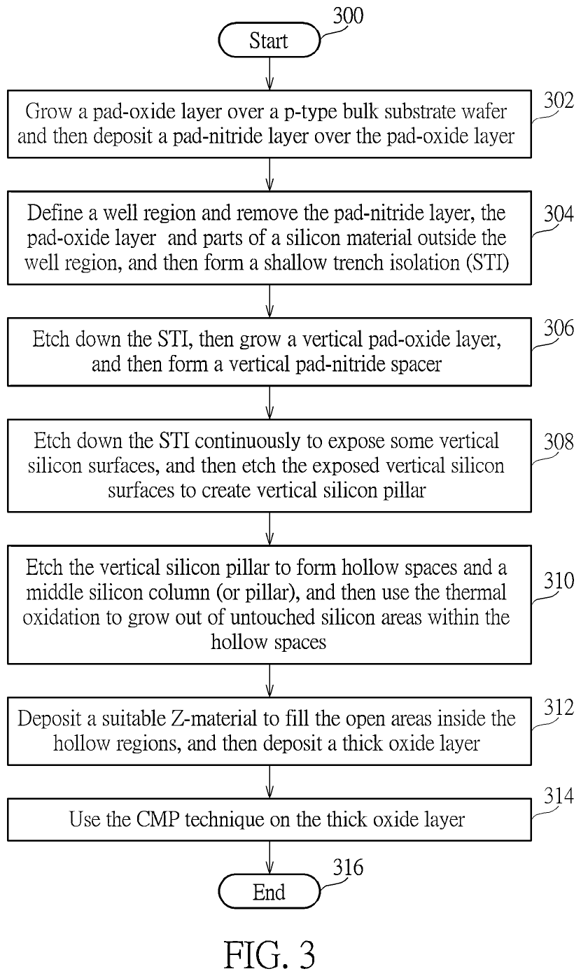

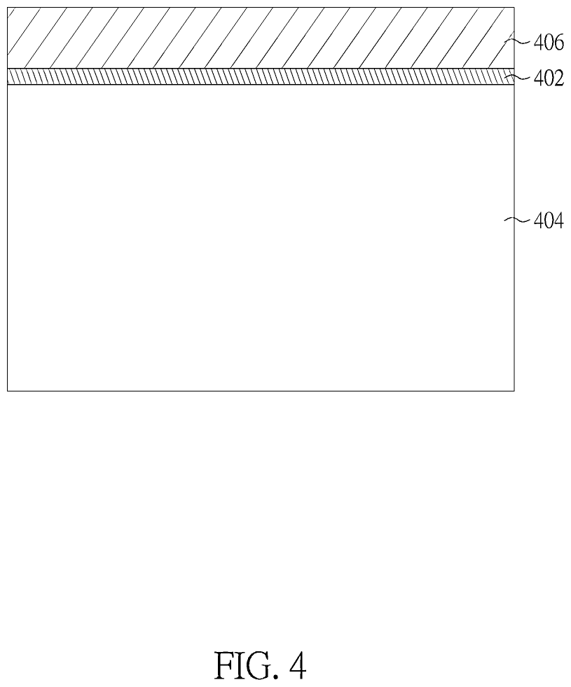

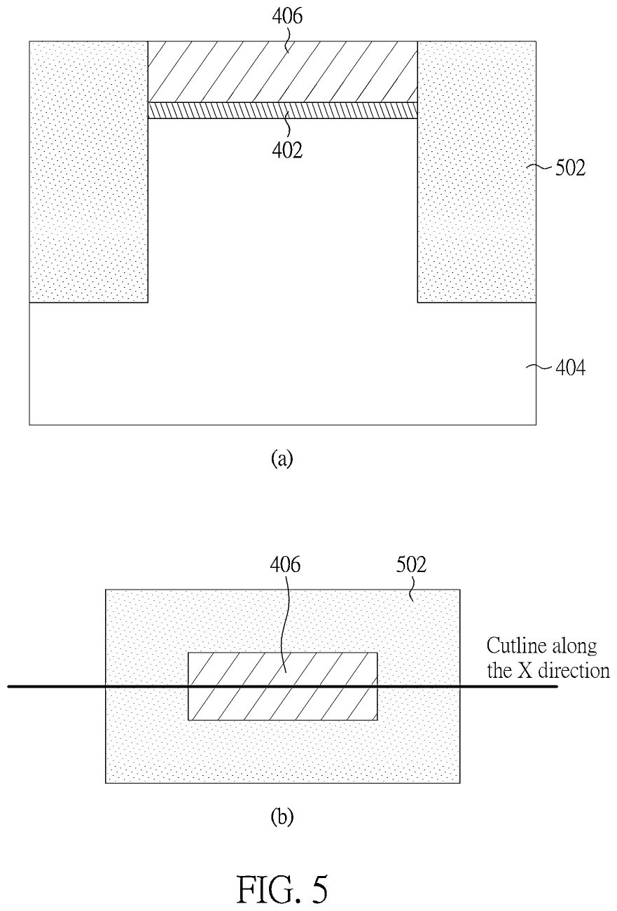

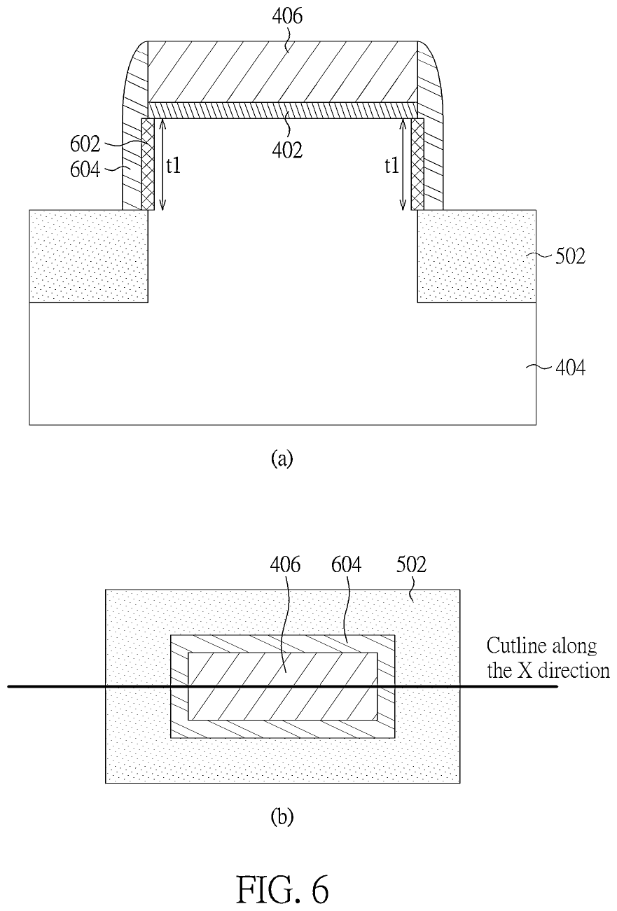

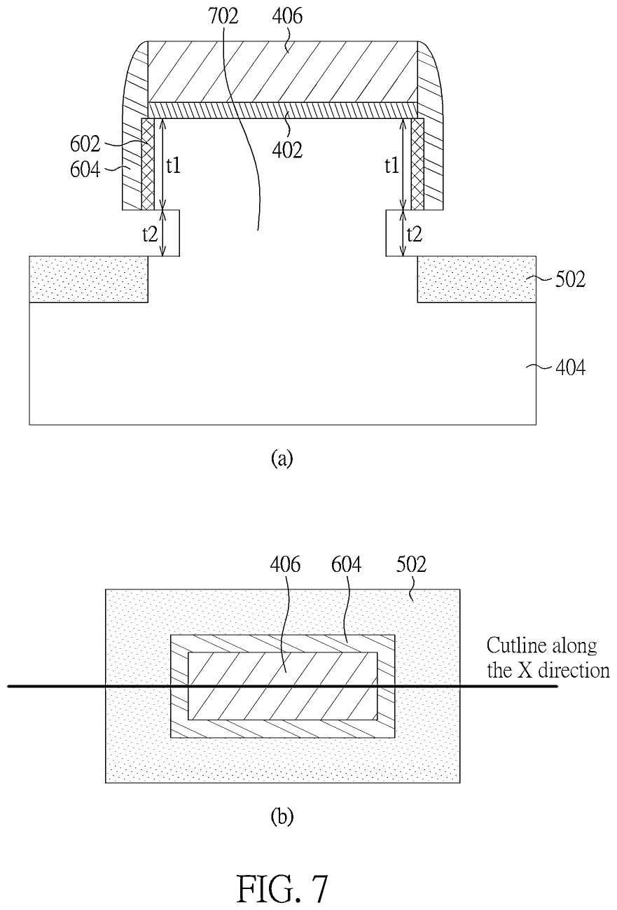

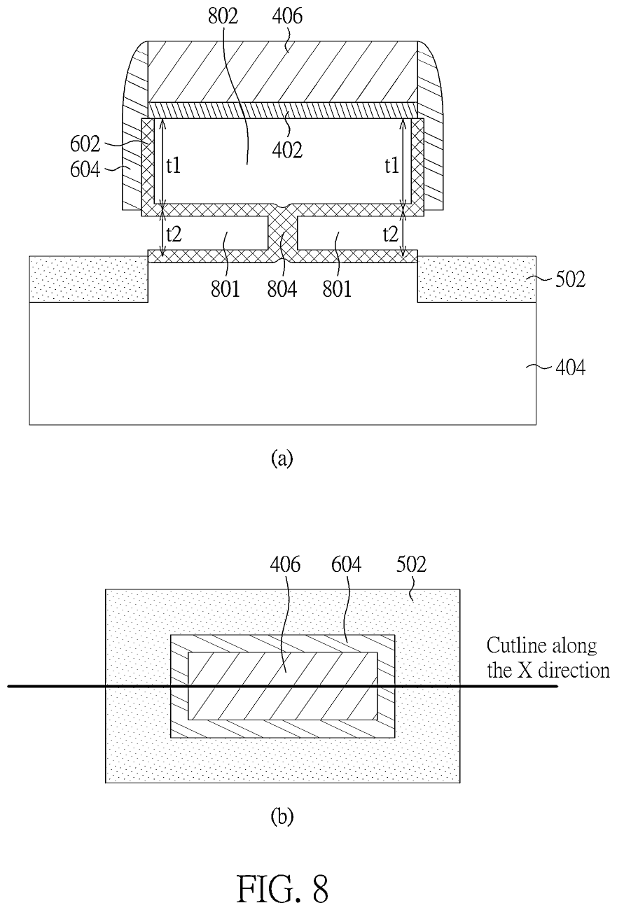

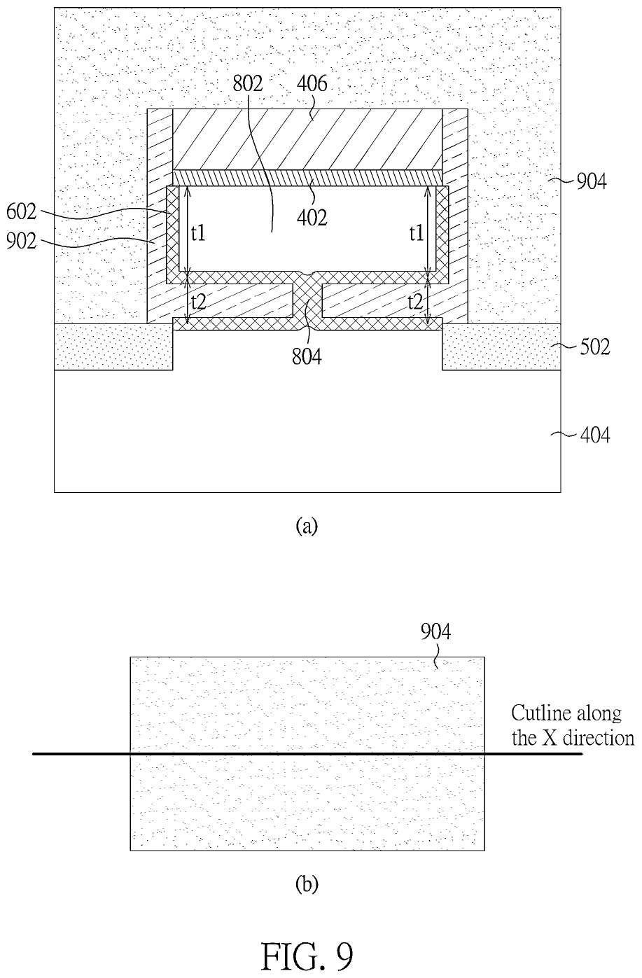

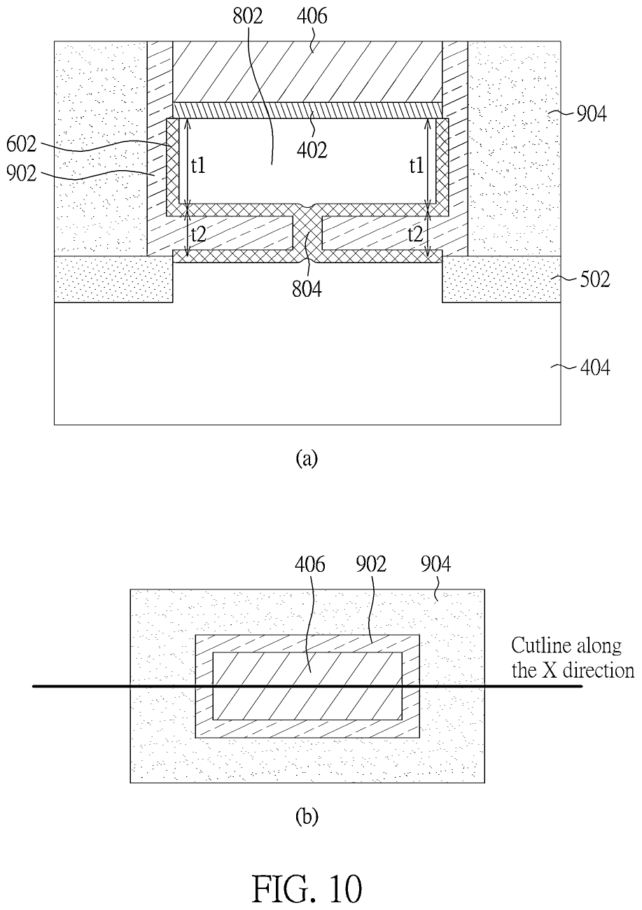

Next, a composite semiconductor substrate with DWTI and HWI can be achieved by a manufacture method described in FIG. 3. Detailed Steps in FIG. 3 are as follows, and please further refer to FIG. 4, FIG. 5, FIG. 6, FIG. 7, FIG. 8, FIG. 9, and FIG. 10:

Step 300: Start.

Step 302: Grow a pad-oxide layer 402 over a p-type bulk substrate wafer 404 and then deposit a pad-nitride layer 406 over the pad-oxide layer 402 (FIG. 4).

Step 304: Define a well region and remove the pad-nitride layer 406, the pad-oxide layer 402 and parts of a silicon material outside the well region, and then form a shallow trench isolation (STI) 502 (FIG. 5).

Step 306: Etch down the STI 502, then grow a vertical pad-oxide layer 602, and then form a vertical pad-nitride spacer 604 (FIG. 6).

Step 308: Etch down the STI 502 continuously to expose some vertical silicon surfaces, and then etch the exposed vertical silicon surfaces to create vertical silicon pillar 702 (FIG. 7).

Step 310: Etch the vertical silicon pillar 702 to form hollow spaces 801 and a middle silicon column (or pillar), and then use the thermal oxidation to grow out of untouched silicon areas within the hollow spaces 801 (FIG. 8).

Step 312: Deposit a suitable Z-material 902 to fill the open areas inside the hollow regions 801, and then deposit a thick oxide layer 904 (FIG. 9).

Step 314: Use the CMP technique on the thick oxide layer 904 (FIG. 10).

Step 316: End.

Described in the following manufacture method is one of several potential processing methods to form both DWTI and HWI. In Step 302, as shown in FIG. 4, first grow the pad-oxide layer of thermal over the p-type wafer substrate. Then deposit the pad-nitride layer 406 over the pad-oxide layer 402.

In Step 304, as shown in FIG. 5(a), use a photolithography masking technique to define the well region and etch away the pad-nitride layer 406, the pad-oxide layer 402 and the parts of a silicon material outside the well region by an anisotropic etching technique to create trenches. Deposit (e.g. chemical vapor deposition, CVD) an oxide layer to fill these trenches with resulted overflown thick oxide layer over the wafer surface and then use a CMP (Chemical and Mechanical Polishing) technique to remove the excess oxide layer to form the STI 502, wherein a top surface of the STI 502 is in level up to the top surface of the pad-nitride layer 406. In addition, FIG. 5(b) is a top view corresponding to FIG. 5(a), wherein FIG. 5(a) is a cross-section view along a cutline of an X direction shown in FIG. 5(b).

In Step 306, as shown in FIG. 6(a), use the anisotropic etching technique to remove the part of the STI 502 in a depth measured from the planar surface down by a depth of t1 to expose a vertical silicon surface. Then, grow thermally a thin oxide layer over the exposed vertical silicon surface (called the vertical pad-oxide 602) and deposit a thin nitride layer. Then use the anisotropic etching technique to etch some thickness of exposed nitride layer to form the vertical pad-nitride spacer 604 along the trench sidewalls to stand on top of the STI 502. In addition, FIG. 6(b) is a top view corresponding to FIG. 6(a), wherein FIG. 6(a) is a cross-section view along a cutline of an X direction shown in FIG. 6(b).

In Step 308, as shown in FIG. 7(a), use the anisotropic etching technique to remove some thickness t2 of the exposed STI 502 so that some vertical silicon surfaces are exposed below the vertical pad-oxide layer 602 and the vertical pad-nitride spacer 604. These exposed silicon surfaces have a crystalline orientation of (110).

As shown in FIG. 7(a), use a suitable wet etching (referred to Reference [1] Prem Pal, Kazuo Sato et al. “Surfactant Adsorption on Single-Crystal silicon Surfaces in TMAH Solution: Orientation-Dependent Adsorption Detected by In Situ Infrared Spectroscopy” JOURNAL OF MICROELECTROMECHANICAL SYSTEMS, VOL. 18, NO. 6, December 2009 pp 1345-1356) to start an etching process. Both the pad-nitride layer 406 over the planar surface and the vertical pad-nitride spacer 604 are used as a vertical mask to stop some wet etching over the pad-nitride layer 406 and the vertical pad-nitride spacer 604. Therefore the exposed vertical (110) silicon surfaces are gradually etched away in a rate of approximate 300 nm per minute. During this wet etching process, the gradually exposed upper and bottom horizontal silicon surfaces of the crystalline orientation of (100) due to the horizontal removal processing on some exposed (110) silicon surfaces are thus gradually subject to the wet-etching chemical recipe. However, Reference [1] proved that a much slower etching rate of removing the (100) silicon structure can be achieved. As a result a horizontal silicon layer from the vertical layer of thickness t1 below the wafer planar surface to the thickness down to (t1+t2) should be well removed to create a hollow structure but without falling apart as the etching rate can be well controlled to leave the mechanically-strong enough vertical silicon pillar 702. In addition, FIG. 7(b) is a top view corresponding to FIG. 7(a), wherein FIG. 7(a) is a cross-section view along a cutline of an X direction shown in FIG. 7(b).

In Step 310, as shown in FIG. 8(a), again, etch the vertical silicon pillar 702 by suitably controlling the etching rate so that the hollow spaces 801 are underneath a silicon island 802 are created and the middle silicon column (or pillar) remains firmly at the middle of the silicon island 802 underneath the pad-oxide layer 402 and has been left in an untouched state. Although a wet etching process is described as above, a dry etching technique to make the etching rate over the (110) silicon lattice much faster than that over the (100) silicon lattice should also be applicable.

As shown in FIG. 8(a), use the thermal oxidation (a wet process can achieve faster oxidation rate than a dry process; either one can be used by choice) to grow out of these untouched silicon areas until a complete isolated oxide layer 804 has been accomplished. Meanwhile some oxide layers are grown on the top and bottom surfaces in the hollow spaces 801. In addition, FIG. 8(b) is a top view corresponding to FIG. 8(a), wherein FIG. 8(a) is a cross-section view along a cutline of an X direction shown in FIG. 8(b).

In Step 312, as shown in FIG. 9(a), then the CVD process is carried on with the suitable Z-material 902 to fill the open areas inside the hollow regions 801, wherein the Z-material 902 can be either oxide, SiON, or some high-thermal-conductivity material such as an insulator like Alumina nitride or Diamond or even a conductive layer like TiN layers. Such the Z-material 902 servers both complete isolation purpose and helping better thermal heat dissipation to reduce box-well raised temperatures due to device operations. By so far a method of creating the Horizontal-well-Isolation (HWI) is invented and disclosed.

Then the vertical pad-nitride 604 can be removed; due to the suitable design the pad-nitride layer 406 is still thick enough to be remained. Or the vertical pad-nitride spacer 604 can stay without being removed. As shown in FIG. 9(a), then the thick oxide layer 904 (or the Z-material 902) can be deposited on the pad-nitride layer 406 and the STI 502. In addition, FIG. 9(b) is a top view corresponding to FIG. 9(a), wherein FIG. 9(a) is a cross-section view along a cutline of an X direction shown in FIG. 9(b). Thus, either the horizontal-well-Isolation region or deep well trench isolation region (or both) could include the Z-material 902 which could be the high-thermal-conductivity material, and the thermal conductivity of the Z-material is higher than that of the SiO₂ or Silicon. Moreover, even the shallow trench isolation (STI) region in any well region of the present invention could the high-thermal-conductivity material

In Step 314, as shown in FIG. 10(a), use the CMP technique on the thick oxide layer 904 to create a planar surface in line up with the pad-nitride layer 406. Therefore the Deep-well-Trench-Isolation (DWTI) is created. In addition, FIG. 10(b) is a top view corresponding to FIG. 10(a), wherein FIG. 10(a) is a cross-section view along a cutline of an X direction shown in FIG. 10(b).

There are many various ways in silicon processings to achieve this kind of Box-well isolation in both vertical and horizontal isolation integration. The above examples just illustrated that how either HWI and DWTI can be formed at separate steps but it should be straightforward that they can be realized simultaneously for the re-filling steps. Furthermore included in this embodiment are just a method to prove such an innovative Box-well structure is not hard to be implemented and realized.

Once the new Box-wells are created as stated above, voltage sources required for various wells can be well designed and supplied by using suitable diffusion areas with suitable metal contacts, e.g. n+ diffusion areas inside the box n-well or p+ diffusion areas inside the box p-well and these diffusion areas and Box-wells are fully isolated from one another without using the complex p/n-junction isolation. Surely the undesirable latch-up phenomena will be significantly diminished.

To sum up, the advantages of creating Box-well structures to separate desirable device types from one another in forming CMOS technology include (1) Box-wells are fully isolated from one another; (2) Eliminate the complex p/n-junction isolations in the conventional CMOS process; (3) It should significantly reduce the Latch-up problems which CMOS devices mostly suffer from; (4) Minimize the leakage mechanism due to p/n junction isolation among wells and devices due to incomplete isolations of various wells; (5) Much better scalable in both vertical and horizontal dimensions as the CMOS circuits/devices must be further scaled; (6) Power dissipation due to junction isolations should be reduced; (7) Noise disturbance should be reduced, especially due to long-distance drifted minority carriers; (8) If the suitable Z-material is used, the thermal dissipation should be improved and thus the thermal temperature due to hot operations can be improved; (9) No complicated Triple well formation process is required, and well separation due to Triple well process can be decreased; (10) If the wafer must be made thinner, the mechanical strengths due to Box-well with both HWI and DWTI should be helpful.

The vertical depth of the deep well trench isolation region, in one embodiment, could be 400˜1200 nm. Moreover, since there is no need for the double-wells or triple wells in the present invention, the vertical depth of the well region in FIG. 2 could be around 40˜100 nm, and in such case the vertical depth of the deep well trench isolation region could be 50˜400 nm.

Although the present invention has been illustrated and described with reference to the embodiments, it is to be understood that the invention is not to be limited to the disclosed embodiments, but on the contrary, is intended to cover various modifications and equivalent arrangements included within the spirit and scope of the appended claims.

What is claimed is:

1. A composite semiconductor substrate, comprising:
a bulk semiconductor substrate with an original semiconductor surface and with a first doping type; and
a first well region in the bulk semiconductor substrate with a second doping type, wherein the first doping type is different from the second doping type;
wherein there is no PN junction between the bulk semiconductor substrate and the first well region.

2. The composite semiconductor substrate in claim 1, further comprising:
a deep well trench isolation region surrounding sidewalls of the first well region; and
a horizontal well isolation region under a bottom surface of the first well region;
wherein a combination of the deep well trench isolation region and the horizontal well isolation region fully isolates the first well region from other portion of the bulk semiconductor substrate.

3. The composite semiconductor substrate in claim 2, wherein two sidewalls of the horizontal well isolation region abut against the deep well trench isolation region.

4. The composite semiconductor substrate in claim 2, wherein a vertical depth of the deep well trench isolation region is 50˜400 nm or 400˜1200 nm.

5. The composite semiconductor substrate in claim 2, wherein a vertical depth of the horizontal well isolation region is 50˜200 nm.

6. The composite semiconductor substrate in claim 1, wherein either the deep well trench isolation region or the horizontal well isolation region includes a high-thermal-conductivity material which has a thermal conductivity higher than that of the SiO₂ or silicon.

7. The composite semiconductor substrate in claim 1, wherein the first doping type is p doping type, and the second doping type is n doping type.

8. The composite semiconductor substrate in claim 7, further comprising:
a PMOS (p-type Metal-Oxide-Semiconductor) transistor in the first well region; and
a shallow trench isolation region surrounding the PMOS transistor;
wherein a vertical depth of the deep well trench isolation region is larger than that of the shallow trench isolation region.

9. A composite semiconductor substrate, comprising:
a bulk semiconductor substrate with an original semiconductor surface and with a first doping type; and
a first well region in the bulk semiconductor substrate with a second doping type;
wherein there is no electrical current path between a bottom of the first well region and other portion of the bulk semiconductor substrate, and there is no electrical current path between sidewalls of the first well region and the other portion of the bulk semiconductor substrate.

10. The composite semiconductor substrate in claim 9, further comprising:
a deep well trench isolation region surrounding sidewalls of the first well region; and
a horizontal well isolation region under a bottom surface of the first well region;
wherein a combination of the deep well trench isolation region and the horizontal well isolation region fully isolates the first well region from other portion of the bulk semiconductor substrate.

11. The composite semiconductor substrate in claim 10, wherein the horizontal well isolation region comprising a material made of oxide, nitride, or high thermal conductivity material.

12. The composite semiconductor substrate in claim 10, wherein the horizontal well isolation region comprising two oxide layers and a high thermal conductivity layer between the two oxide layers.

13. The composite semiconductor substrate in claim 10, wherein both the first doping type and the second doping type are p doping type.

14. The composite semiconductor substrate in claim 13, wherein a doping concentration of the first doping type is different from that of the second doping type.

15. The composite semiconductor substrate in claim 13, further comprising:
an NMOS (n-type Metal-Oxide-Semiconductor) transistor in the first well region; and
a shallow trench isolation region surrounding the NMOS transistor;
wherein a vertical depth of the deep well trench isolation region is larger than that of the shallow trench isolation region.

16. The composite semiconductor substrate in claim 15, wherein either the deep well trench isolation region or the shallow trench isolation region includes a high-thermal-conductivity material which has a thermal conductivity higher than that of the SiO₂ or silicon.

17. A composite semiconductor substrate, comprising:
a bulk semiconductor substrate with an original semiconductor surface and with a first doping type;
a first well region in the bulk semiconductor substrate with a second doping type; and
a second well region in the bulk semiconductor substrate with the first doping type;
wherein there is no electrical current path between a bottom of the first well region and other portion of the bulk semiconductor substrate, and there is no electrical current path between a bottom of the second well region and the other portion of the bulk semiconductor substrate.

18. The composite semiconductor substrate in claim 17, further comprising:
a first deep well trench isolation region surrounding sidewalls of the first well region; and
a first horizontal well isolation region under a bottom surface of the first well region;
wherein a combination of the first deep well trench isolation region and the first horizontal well isolation region fully isolates the first well region from other portion of the bulk semiconductor substrate.

19. The composite semiconductor substrate in claim 18, further comprising:
a second deep well trench isolation region surrounding sidewalls of the second well region; and
a second horizontal well isolation region under a bottom surface of the second well region;
wherein a combination of the second deep well trench isolation region and the second horizontal well isolation region fully isolates the second well region from other portion of the bulk semiconductor substrate.

20. The composite semiconductor substrate in claim 19, wherein a vertical depth of the first well region or the second well region is around 40˜100 nm.

21. The composite semiconductor substrate in claim 20, further comprising:
an NMOS transistor in the first well region; and
a first shallow trench isolation region surrounding the NMOS transistor;
wherein a vertical depth of the first deep well trench isolation region is larger than that of the first shallow trench isolation region.

22. The composite semiconductor substrate in claim 20, further comprising:
a PMOS transistor in the second well region; and
a second shallow trench isolation region surrounding the PMOS transistor;
wherein a vertical depth of the second deep well trench isolation region is larger than that of the second shallow trench isolation region.
